(19) United States
(12) Patent Application Publication
(10) Pub. No.: US 2019/0136132 A1
(43) Pub. Date: May 9, 2019

(54) COMPOSITION FOR ETCHING, METHOD OF ETCHING SILICON NITRIDE LAYER, AND METHOD FOR MANUFACTURING SEMICONDUCTOR DEVICE

(71) Applicant: SAMSUNG ELECTRONICS CO., LTD., Suwon-si (KR)

(72) Inventors: HOON HAN, ANYANG-SI (KR); SANG WON BAE, SUWON-SI (KR); YOUNG TAEK HON, HWASEONG-SI (KR); JAEWAN PARK, SEJONG-SI (KR); JINUK LEE, SEJONG-SI (KR); JUNGHUN LIM, DAEDEOK-GU (KR)

(73) Assignee: SOULBRAIN CO., LTD., SEONGNAM-SI (KR)

(21) Appl. No.: 15/973,486

(22) Filed: May 7, 2018

(30) Foreign Application Priority Data
Nov. 7, 2017 (KR) 10-2017-0147532

(51) Int. Cl. C09K 13/06; H01L 21/311

(52) U.S. Cl. CPC C09K 13/06; H01L 21/31144; H01L 21/31111

(57) ABSTRACT

A composition for etching may include phosphoric acid, an ammonium-based compound, at least one of hydrochloric acid or a polyphosphate-based compound, and a silicon-containing compound.

### CROSS-REFERENCE TO RELATED APPLICATIONS

This U.S. non-provisional patent application claims priority under 35 U.S.C. § 119 of Korean Patent Application No. 10-2017-0147532, filed on Nov. 7, 2017, the entire contents of which are hereby incorporated by reference.

### BACKGROUND

The present disclosure herein relates to a composition for etching, a method for manufacturing a semiconductor device using the same, and more particularly, to a composition for etching used for etching a silicon nitride layer, and a method for manufacturing a semiconductor device using the same.

Semiconductor devices are required to increase the degree of integration and reliability thereof to satisfy excellent performance and low price which are required by the consumer. As the degree of integration of semiconductors increases, the reliability and/or electrical characteristics of the semiconductor devices may be more influenced by damages on the elements constituting the semiconductor device during the manufacturing process of the semiconductor device.

In particular, during the manufacturing process of semiconductor devices, the minimization of by-products formed by an etching process while maintaining high etch selectivity of a layer material to be etched to another layer material is required, because the by-products may induce defects of layer materials. Accordingly, recently, research on compositions for etching, which have high etch selectivity and decrease the generation of by-products, is being conducted.

### SUMMARY

The present disclosure provides a composition for etching having high etch selectivity with respect to a nitride layer, and a method of etching a silicon nitride layer using the same.

The present disclosure also provides a method for manufacturing a semiconductor device having improved reliability.

The disclosure relates to a composition for etching and a method for manufacturing a semiconductor device using the same. The composition for etching according to the disclosure may include phosphoric acid, an ammonium-based compound, hydrochloric acid or a polyphosphate-based compound, and a silicon-containing compound represented by Formula 2:

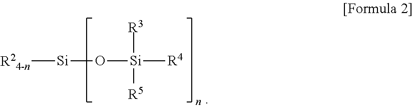

In Formula 2, R² is any one selected from hydrogen, an alkyl group of 1 to 10 carbon atoms, an amino alkyl group of 1 to 10 carbon atoms, an amino alkoxy group of 1 to 10 carbon atoms, and an alkoxy amino group of 1 to 10 carbon atoms.

R³, R⁴ and R⁵ are each independently hydrogen, an alkyl group of 1 to 10 carbon atoms, an amino alkyl group of 1 to 10 carbon atoms, an amino alkoxy group of 1 to 10 carbon atoms, an alkoxy amino group of 1 to 10 carbon atoms, or an alkyl substituted or unsubstituted amino group of 1 to 10 carbon atoms. At least one of R³, R⁴ or R⁵ is an alkoxy amino group of 1 to 10 carbon atoms, or an alkyl substituted or unsubstituted amino group of 1 to 10 carbon atoms, and n is 2 or 3.

In an embodiment of the disclosure, a method of etching a silicon nitride layer may include preparing a substrate on which a silicon nitride layer is formed and performing an etching process on the silicon nitride layer using a composition for etching to remove the silicon nitride layer. The composition for etching includes phosphoric acid, an ammonium-based compound, hydrochloric acid or a polyphosphate-based compound, and a silicon-containing compound represented by Formula 2:

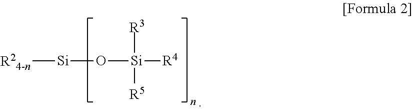

In Formula 2, R² is any one selected from hydrogen, an alkyl group of 1 to 10 carbon atoms, an amino alkyl group of 1 to 10 carbon atoms, an amino alkoxy group of 1 to 10 carbon atoms, and an alkoxy amino group of 1 to 10 carbon atoms.

R³, R⁴ and R⁵ are each independently hydrogen, an alkyl group of 1 to 10 carbon atoms, an amino alkyl group of 1 to 10 carbon atoms, an amino alkoxy group of 1 to 10 carbon atoms, an alkoxy amino group of 1 to 10 carbon atoms, or an alkyl substituted or unsubstituted amino group of 1 to 10 carbon atoms. At least one of R³, R⁴ or R⁵ is an alkoxy amino group of 1 to 10 carbon atoms or an alkyl substituted or unsubstituted amino group of 1 to 10 carbon atoms, and n is 2 or 3.

In an embodiment of the disclosure, a method for manufacturing a semiconductor device may include: (1) forming a stacked structure by alternately and repeatedly forming insulating layers and sacrificing layers on a substrate, (2) forming a trench penetrating the stacked structure, and (3) removing the sacrificing layers by performing an etching process using a composition for etching. The composition for etching includes phosphoric acid, an ammonium-based compound, hydrochloric acid or a polyphosphate-based compound, and a silicon-containing compound represented by Formula 2:

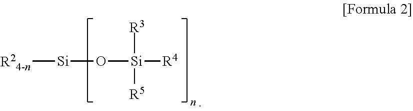

In Formula 2, R² is any one selected from hydrogen, an alkyl group of 1 to 10 carbon atoms, an amino alkyl group of 1 to 10 carbon atoms, an amino alkoxy group of 1 to 10 carbon atoms, and an alkoxy amino group of 1 to 10 carbon atoms.

R³, R⁴ and R⁵ are each independently hydrogen, an alkyl group of 1 to 10 carbon atoms, an amino alkyl group of 1 to 10 carbon atoms, an amino alkoxy group of 1 to 10 carbon atoms, an alkoxy amino group of 1 to 10 carbon atoms, or an alkyl substituted or unsubstituted amino group of 1 to 10 carbon atoms. At least one of R³, R⁴ or R⁵ is an alkoxy amino group of 1 to 10 carbon atoms or an alkyl substituted or unsubstituted amino group of 1 to 10 carbon atoms, and n is 2 or 3.

In an embodiment of the disclosure, a method of etching a silicon nitride layer includes: (1) preparing a substrate on which a silicon nitride layer is formed and a silicon oxide layer is formed over a masked portion of the silicon nitride layer but not over an unmasked portion of the silicon nitride layer and (2) applying, through an etching process, an etching composition to the silicon nitride layer and the silicon oxide layer to remove the unmasked portion of the silicon nitride layer but not the masked portion of the silicon nitride layer. The etching composition comprises: (a) phosphoric acid that reacts with the silicon nitride layer to remove silicon nitride and reacts with the silicon oxide layer to remove silicon oxide and (2) a silicon-containing compound that reacts with the silicon oxide layer so as to reduce an amount of silicon oxide removed by the etching process, but less readily reacts with the silicon nitride layer and, thereby, less readily reduces an amount of silicon nitride removed by the etching process.

### BRIEF DESCRIPTION OF THE FIGURES

The accompanying drawings are included to provide a further understanding of the disclosure, and are incorporated in and constitute a part of this specification. The drawings illustrate exemplary embodiments of the disclosure and, together with the description, serve to explain principles of the disclosure. In the drawings:

FIG. 1 is a plan view of a semiconductor device according to exemplary embodiments;

FIGS. 2 to 8 are illustrated for explaining a method for manufacturing a semiconductor device according to exemplary embodiments; and

FIG. 9 is an enlarged view on region A of FIG. 8.

### DETAILED DESCRIPTION

In the description, the term “substituted or unsubstituted” may mean substituted or unsubstituted with at least one substituent selected from the group consisting of a hydrogen atom, a deuterium atom, a halogen atom, a cyano group, a nitro group, an amino group, a silyl group, a boron group, a phosphine oxide group, a phosphine sulfide group, an alkyl group, an alkenyl group, an aryl group, and a heterocyclic group. In detail, the term “substituted or unsubstituted” may mean substituted or unsubstituted with at least one substituent selected from the group consisting of a hydrogen atom, a deuterium atom, an alkyl group, an amino group, a silyl group, and an alkoxy group. In addition, each of the substituents may be substituted or unsubstituted. For example, a methylamino group may be interpreted as an amino group.

In the description, examples of the halogen atom may include a fluorine atom, a chlorine atom, a bromine atom and an iodine atom.

In the description, the alkyl group may be a linear alkyl group, a branched alkyl group, or a cyclic alkyl group. The carbon number of the alkyl group is not specifically limited but may be from 1 to 10.

In the description, the alkyl group may be a linear alkyl group, a branched alkyl group, or a cyclic alkyl group. Examples of the alkyl group may include, but are not limited to, methyl, ethyl, n-propyl, isopropyl, n-butyl, t-butyl, butyl, 2-ethylbutyl, 3,3-dimethylbutyl, n-pentyl, i-pentyl, neopentyl, t-pentyl, cyclopentyl, 1-methylpentyl, 3-methylpentyl, 2-ethylpentyl, 4-methyl-2-pentyl, n-hexyl, 1-methylhexyl, 2-ethylhexyl, 2-butylhexyl, cyclohexyl, 4-methylcyclohexyl, 4-t-butylcyclohexyl, n-heptyl, 1-methylheptyl, 2,2-dimethylheptyl, 2-ethylheptyl, 2-butylheptyl, n-octyl, t-octyl, 2-ethyloctyl, 2-butyloctyl, 2-hexyloctyl, 3,7-dimethyloctyl, cyclooctyl, n-nonyl, and/or n-decyl, etc.

In the description, the silyl group may include an alkylsilyl group and an arylsilyl group. Examples of the silyl group may include, but are not limited to, a trimethylsilyl group, a triethylsilyl group, a t-butyldimethylsilyl group, a vinyldimethylsilyl group, a propyldimethylsilyl group, a triphenylsilyl group, a diphenylsilyl group, and/or a phenylsilyl group, etc.

In the description, the carbon number of the amino group is not specifically limited, and may be 1 to 10. The amino group may include, but is not limited to, an alkylamino group and an arylamino group. Examples of the amino group may include a methylamino group, an ethylamino group, a dimethylamino group, a diethylamino group, and/or an ethylmethylamino group.

In the description, the carbon number of the aminoalkyl group may be 1 to 10.

In the description, the carbon number of the alkoxy group is not specifically limited and may be 1 to 10. The alkoxy group may include an alkyl alkoxy group and an aryl alkoxy group. Examples of the alkoxy group may include, but are not limited to, a methyl alkoxy group, an ethyl alkoxy group, a propyl alkoxy group, a butyl alkoxy group, a pentyl alkoxy group, a hexyl alkoxy group, a heptyl alkoxy group, an octyl alkoxy group, a nonyl alkoxy group, and/or a decyl alkoxy group, etc.

Hereinafter, the composition for etching according to the disclosure will be explained.

According to the disclosure, a composition for etching (hereinafter referred to as “etching composition”) may include phosphoric acid, an ammonium-based compound, a silicon-containing compound, hydrochloric acid, and a polyphosphate-containing compound. The etching composition may be used for etching a silicon-containing material. For example, the etching composition may be used for etching a silicon nitride layer or a silicon oxide layer. The etching of a silicon nitride layer using the etching composition may be performed according to Reaction 1 below. The etching of a silicon oxide layer using a silicon composition may be performed according to Reaction 2 below. However, in an etching process using the etching composition, the etch rate of the silicon nitride layer may be greater than the etch rate of the silicon oxide layer. In the description, the etching of the silicon nitride layer may mean the removal of silicon nitride, and the etching of the silicon oxide layer may mean the removal of silicon oxide. The silicon nitride may be represented by SixNy. The silicon oxide may include SixOy (where x and y are each independently a positive integer).

3Si₃N₄+4H₃PO₄+27H₂O→4(NH₄)₃PO₄+9SiO₂H₂O [Reaction 1]

SiO₂+4H⁺+4e⁻→Si+2H₂O [Reaction 2]

Referring to Reaction 1, phosphoric acid reacts with silicon nitride, and the silicon nitride may be removed. The composition ratio of the phosphoric acid may be from about 65 wt % to about 97 wt %. In the present specification, the composition ratio means the composition ratio with respect to the composition. If the amount of the phosphoric acid is less than about 65 wt % of the etching composition, silicon nitride may not be easily removed, or etching by-products may be formed during an etching process. In the description, the composition ratio of the phosphoric acid may mean the composition ratio of an aqueous solution of 85% phosphoric acid. That is, “about 65 wt % of the composition ratio of the phosphoric acid” may mean “about 65 wt % of the aqueous solution of 85% phosphoric acid based on the etching composition”.

Referring to Reaction 2, phosphoric acid provides hydrogen ions and may react with silicon oxide. If the amount of the phosphoric acid is greater than about 97 wt % of the etching composition, the reaction rate of phosphoric acid and silicon oxide may increase. In this case, etch selectivity of the silicon nitride layer with respect to the silicon oxide layer may be low.

The silicon-containing compound may include at least one of the materials represented by Formula 1 or Formula 2 below. In an embodiment, the silicon-containing compound represented by Formula 1 may be aminopropyl silanetriol.

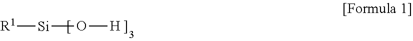

In Formula 1, R¹ may be any one selected from an amino alkyl group of 1 to 10 carbon atoms, an amino alkoxy group of 1 to 10 carbon atoms, and an alkoxy amino group of 1 to 10 carbon atoms.

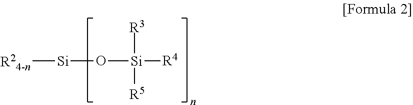

In Formula 2, R² may be any one selected from hydrogen, an alkyl group of 1 to 10 carbon atoms, an amino alkyl group of 1 to 10 carbon atoms, an amino alkoxy group of 1 to 10 carbon atoms, and an alkoxy amino group of 1 to 10 carbon atoms, and R³, R⁴ and R⁵ are each independently hydrogen, an alkyl group of 1 to 10 carbon atoms, an amino alkyl group of 1 to 10 carbon atoms, an amino alkoxy group of 1 to 10 carbon atoms, an alkoxy amino group of 1 to 10 carbon atoms or a substituted or unsubstituted amino group. The substituted amino group may be an alkyl substituted amino group, the alkyl may be a linear or branched alkyl group of 1 to 10 carbon atoms, and n may be 2 or 3. In Formula 2, at least one of R³, R⁴ or R⁵ may be the alkoxy amino group of 1 to 10 carbon atoms or a substituted or unsubstituted amino group.

According to an embodiment, in Formula 1 and Formula 2, the alkoxy amino group may be represented by Formula 3a, and the amino alkoxy group may be represented by Formula 3b.

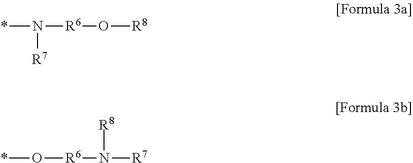

(In Formula 3a and Formula 3b, R⁶ is an alkyl group of 1 to 10 carbon atoms, R⁷ and R⁸ are each independently any one selected from hydrogen and an alkyl group of 1 to 10 carbon atoms, and the total carbon number of R⁶, R⁷ and R⁸ may be 1 to 10. The alkyl group may be a linear alkyl group, a branched alkyl group, or a cyclic alkyl group. * means a bonded part to Si.)

In an embodiment, the silicon-containing compound represented by Formula 2 may be represented by Formula 4 or Formula 5 below, but may be not limited thereto.

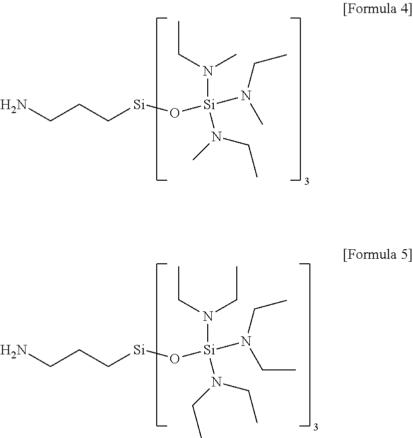

The silicon-containing compound represented by Formula 1 may be obtained by the silylation reaction of silanol (a) and a chlorosilane-based compound (b) as shown in Reaction 1 below.

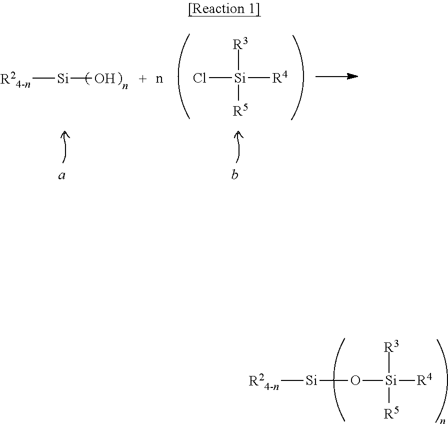

In Reaction 1, R², R³, R⁴, R⁵ and n are the same as defined in Formula 2. The silicon-containing compound represented by Formula 4 may be synthesized by Reaction 2 below.

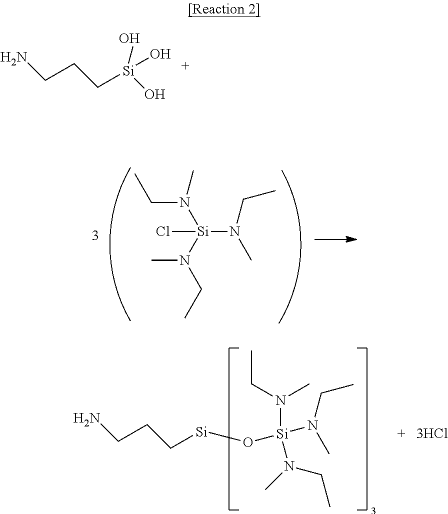

The silicon-containing compound represented by Formula 5 may be synthesized by Reaction 3 below.

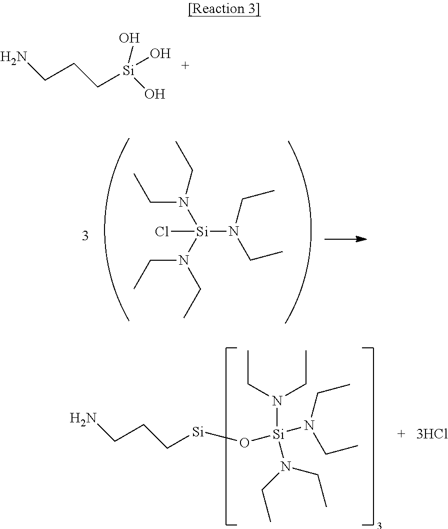

The silicon-containing compound may play the role of increasing the etch selectivity of the silicon nitride layer with respect to the silicon oxide layer. According to exemplary embodiments, the oxygen atom of the silicon-containing compound may make interaction (for example, hydrogen bond) with the surface of the silicon oxide layer. In this case, the oxygen atom of the silicon-containing compound may be an oxygen atom which is directly bonded to a silicon atom. By hydrogen bond, the etching of the silicon oxide layer may be prevented or decreased. The oxygen atom of the silicon-containing compound may not make interaction (for example, hydrogen bond) with the surface of the silicon nitride layer. Accordingly, the etch selectivity of the silicon nitride layer with respect to the silicon oxide layer may increase.

If the amount of the silicon-containing compound is less than about 0.01 wt % of the etching composition, the etch rate of the silicon oxide layer may increase. In this case, the etch selectivity of the silicon nitride layer with respect to the silicon oxide layer may decrease. If the amount of the silicon-containing compound is greater than about 15 wt % of the etching composition, the etch rate of the silicon nitride layer may decrease. According to exemplary embodiments, the composition ratio of the silicon-containing compound may be from about 0.01 wt % to about 15 wt %.

The bond between silicon and oxygen is relatively unstable and may be easily cleaved. According to exemplary embodiments, the silicon-containing compound represented by Formula 1 or Formula 2 includes nitrogen, and the bond between the silicon atom and the oxygen atom may be stabilized. For example, in the silicon-containing compound of Formula 2, the bond between the silicon atom and the oxygen atom may be stabilized by the bond between the silicon atom and the nitrogen atom. Accordingly, the etch selectivity of the silicon nitride layer with respect to the silicon oxide layer may further increase. In addition, the production of by-products formed by breaking the bond between the silicon atom and the oxygen atom may be prevented or decreased.

In aqueous solution conditions, the ammonium-based compound may mean a compound producing ammonium (NH₄⁺). The ammonium-based compound may include, for example, at least one of ammonia, ammonium chloride, ammonium phosphate, ammonium acetate, ammonium sulfate, ammonium formate, and a metal amine complex. The metal amine complex may be a metal complex including at least one ammonia (NH₃) ligand. If the etching process of the silicon nitride is performed for a long time, the concentration of silicon ions may increase. In an embodiment, the silicon ions may be produced by the product of Reaction 1, SiO₂H₂O. Due to the silicon ions, abnormal growth of the silicon oxide layer may be generated. According to exemplary embodiments, the ammonium-based compound may be dissociated during an etching process to produce ammonium (NE)-Ammonium reacts with the precursor of silicon ions (for example, SiO₂) and may remove the precursor of silicon ions. Accordingly, the abnormal growth of the silicon oxide layer may be prevented. The ammonium-based compound may maintain the etch rate constant in accordance with an etching time.

If the amount of the ammonium-based compound is less than about 0.01 wt % of the etching composition, the silicon oxide layer may grow abnormally, or the etch selectivity of the silicon nitride layer with respect to the silicon oxide layer may be changed in accordance with time. If the amount of the ammonium-based compound is greater than about 10 wt % of the etching composition, the etch rate of the silicon nitride layer and the silicon oxide layer may be changed in accordance with time. According to an embodiment, the composition ratio of the ammonium-based compound may be from about 0.01 wt % to about 10 wt %.

In an etching process, hydrochloric acid may remove SiO₂H₂O which is the product of Reaction 1. For example, SiO₂H₂O which is the product of Reaction 1 may form SiO₂, and hydrochloric acid may react with SiO₂ as Reaction 4 below to remove SiO₂. Accordingly, the abnormal growth of the silicon oxide layer may be further prevented.

4HCl+SiO₂→SiCl₂(↑)+2H₂O [Reaction 4]

The polyphosphate-based compound may be represented by Formula 6 below.

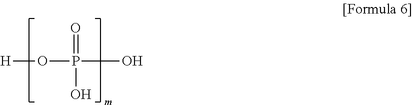

In Formula 6, m is an integer between 1 and 5.

The polyphosphate-based compound may include at least one of pyrophosphoric acid, pyrophosphate, tripolyphosphoric acid and tripolyphosphate. If an etching process is performed for a long time, phosphoric acid may be consumed. In this case, the polyphosphate-based compound may form phosphoric acid. For example, if the polyphosphate-based compound includes pyrophosphoric acid, pyrophosphoric acid may react with water to form phosphoric acid as Reaction 5 below.

H₄P₂O₇+H₂O [symbol] 2H₃PO₄ [Reaction 5]

In the etching process, the concentration of phosphoric acid may be maintained constant in accordance with time due to the polyphosphate-based compound. Accordingly, the etch rate of the silicon nitride layer and the silicon oxide layer may be maintained constant.

According to exemplary embodiments, the composition ratio of the total of hydrochloric acid and the polyphosphate-based compound may be from about 1 wt % to about 10 wt %. If the composition ratio of the total of the hydrochloric acid and the polyphosphate-based compound is less than about 1 wt %, the constant maintenance of the etch rate may be difficult. If the composition ratio of the total of the hydrochloric acid and the polyphosphate-based compound is greater than about 10 wt %, the amount ratios of phosphoric acid, the ammonium-based compound or the silicon-containing compound may decrease. In this case, the etch selectivity of the silicon nitride layer with respect to the silicon oxide layer may decrease. If the hydrochloric acid is included in an excessive amount (for example, greater than about 10 wt % of the etching composition), equipment used for the etching process may be damaged, or the etch rate of the silicon nitride layer may decrease. If the polyphosphate-based compound is excessively included (for example, greater than about 10 wt % of the etching composition), the boiling point of the etching composition may increase. In this case, the etch rate of the silicon nitride layer may decrease in an etching process.

Hereinafter, the method for manufacturing a semiconductor device according to the disclosure will be explained.

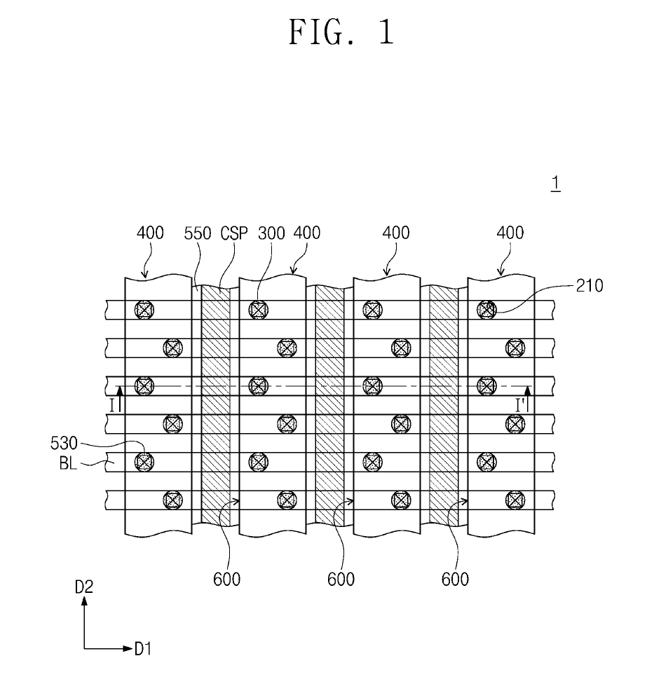

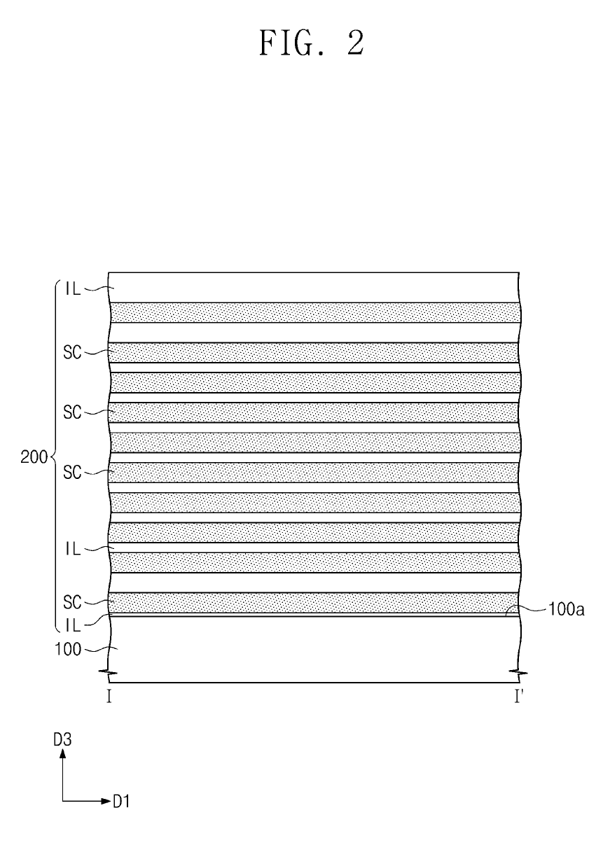

FIG. 1 is a plan view of a semiconductor device according to exemplary embodiments. FIGS. 2 to 8 are illustrated for explaining a method for manufacturing a semiconductor device according to exemplary embodiments and correspond to cross-sectional views taken along line I-I′ of FIG. 1. Hereinafter, the descriptions to the same elements as in the above embodiments will be omitted or mentioned briefly for the purpose of ease and convenience in explanation.

Referring to FIGS. 1 and 2, a stacked structure 200 may be formed on a substrate 100. The substrate 100 may be a bulk silicon substrate, a silicon-on-insulator (SDI) substrate, a germanium substrate, a germanium-on-insulator (GOI) substrate, a silicon-germanium substrate, or a substrate of an epitaxial thin film obtained by conducting selective epitaxial growth (SEG). A first direction D1 and a second direction D2 may be parallel to a top surface 100a of the substrate 100. The second direction D2 may cross the first direction D1. A third direction D3 may be perpendicular to the top surface 100a of the substrate 100.

The stacked structure 200 may include sacrificing layers SC and insulating layers IL. The forming of the stacked structure 200 may include alternately and repeatedly forming the sacrificing layers SC and the insulating layers IL on the substrate 100. The sacrificing layers SC may be formed between the insulating layers IL. The sacrificing layers SC may have etch selectivity with respect to the insulating layers IL. The sacrificing layers SC may include, for example, silicon nitride (for example, SixNy). The insulating layers IL may include silicon oxide (for example, SixOy). The insulating layers IL may be formed using tetraethoxysilane (TEOS), and tetraethoxysilane may be represented by (C₂H₅O)₄Si.

In exemplary embodiments, the sacrificing layers SC may have substantially the same thickness. Alternatively, the thickness of the lowermost sacrificing layer SC and the uppermost sacrificing layer SC among the sacrificing layers SC may be greater than those of the sacrificing layers SC positioned therebetween. In addition, the insulating layers IL may have the same thickness, or the thickness of at least two of the insulating layers IL may be different. The lowermost one of the insulating layers IL may have a smaller thickness than those of the sacrificing layers SC and the insulating layers IL formed thereon. The lowermost layer of the insulating layers IL may be a silicon oxide layer formed by a thermal oxidation process. In the description, the thickness of a certain element may mean a distance in a third direction D3 of the element.

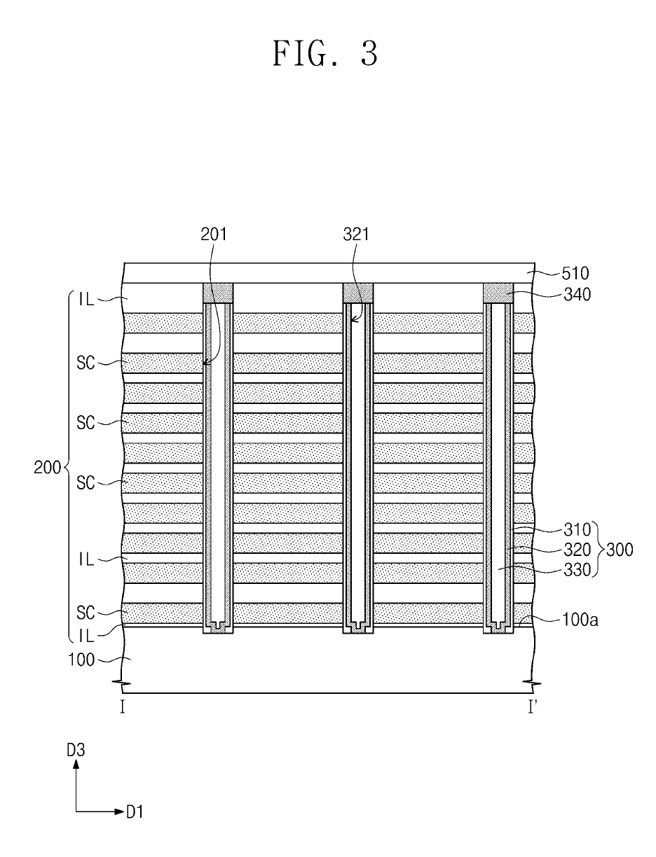

Referring to FIGS. 1 and 3, openings 201 and vertical structures 300 may be formed in the stacked structure 200. The forming of the openings 201 may include forming a mask pattern (not shown) defining the planar positions of the openings 201 on the stacked structure 200, and etching the stacked structure 200 using the mask pattern as an etching mask. The etching of the stacked structure 200 may be performed by an anisotropic etching process.

The openings 201 may penetrate the stacked structure 200. The sidewalls of the openings 201 may expose the sacrificing layers SC and the insulating layers IL. The openings 201 may expose the substrate 100. During forming the openings 201, the top surface 100a of the substrate 100 may be over etched. In this case, the top surface 100a of the substrate 100 exposed by the openings 201 may be recessed to a certain depth.

Each of the openings 201 may be formed in a cylindrical shape or a rectangular hole shape. The lower portions of the openings 201 may have a narrower width than the upper portions thereof. As shown in FIG. 1, the openings 201 may form rows parallel to the second direction D2 in a plan view. The openings 201 between two adjacent rows may be arranged in a zigzag form in the second direction D2. Different from FIG. 1, the openings 201 may form an array arranged along the first direction D1 and the second direction D2. For example, the openings 201 of adjacent two rows may be arranged in the first direction D1 to form an array.

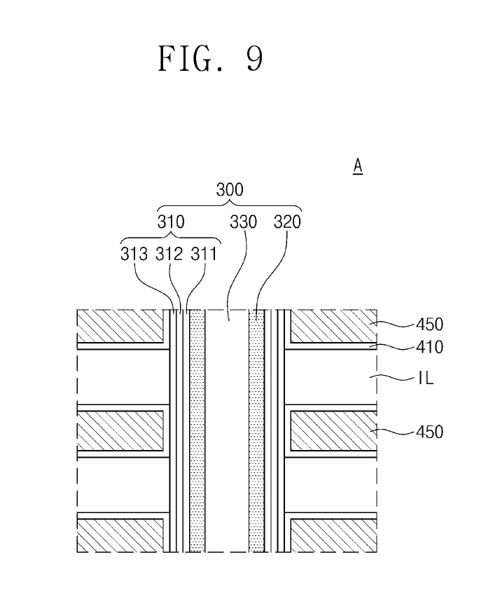

First dielectric patterns 310 may be formed in the openings 201. The first dielectric patterns 310 may cover the sidewalls of the openings 201. The first dielectric patterns 310 may expose the top surface 100a of the substrate 100. The first dielectric patterns 310 may include a single insulating layer or plural insulating layers. The first dielectric patterns 310 may function as a portion of a data storage layer of a charge trap type flash memory transistor. Exemplary embodiments of the first dielectric pattern 310 will be explained later referring to FIG. 9.

Semiconductor patterns 320 may be formed in the openings 201. The semiconductor patterns 320 may include, for example, silicon (Si), germanium (Ge), or a mixture thereof. The semiconductor patterns 320 may have a crystalline structure including at least one of a monocrystalline, amorphous, or polycrystalline structure. The semiconductor patterns 320 may further include doped impurities. In another embodiment, the semiconductor patterns 320 may be intrinsic semiconductor which is an undoped state. The semiconductor patterns 320 may be formed by using a thermal chemical vapor deposition (CVD), plasma enhanced CVD, physical CVD, or atomic layer deposition (ALD) method.

The semiconductor patterns 320 may be formed on the sidewalls of the openings 201 to cover the first dielectric patterns 310. The semiconductor patterns 320 may be extended onto the substrate 100 and may be in contact with a portion of the top surface 100a of the substrate 100, which is exposed by the openings 201. Each of the semiconductor patterns 320 may be formed in a pipe shape, a hollow cylindrical shape, or a cup shape corresponding to one of the openings 201. The semiconductor patterns 320 may define vacant areas 321 in the center portions of the openings 201.

The vacant areas 321 may be filled with buried insulating patterns 330, respectively. The buried insulating patterns 330 may be formed using an insulating material having excellent gap-fill properties. The buried insulating patterns 330 may be formed as, for example, a high density plasma oxide layer, a spin-on-glass (SOG) layer, and/or a VCD oxide layer.

Pads 340 may be formed on the vertical structures 300. The pads 340 may be formed using a semiconductor material doped with impurities or a conductive material such as a metal. The bottom surfaces of the pads 340 may be disposed at a higher level than the top surfaces of the uppermost sacrificing layer SC. A lower capping layer 510 may be formed on the top surface of the vertical structures 300 and the stacked structure 200. The lower capping layer 510 may include an insulating material such as silicon oxide, silicon nitride, and silicon oxynitride.

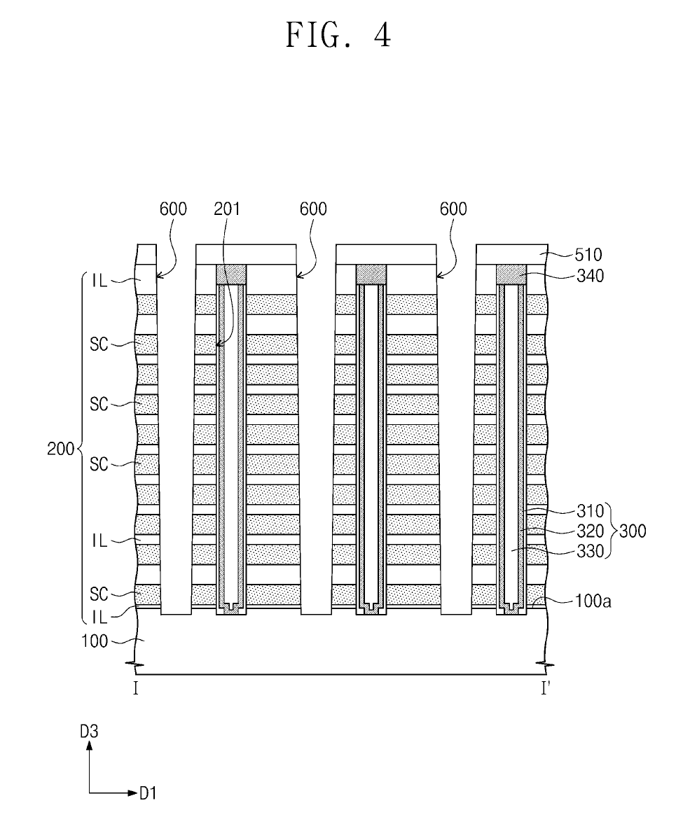

Referring to FIG. 4, trenches 600 may be formed to penetrate the stacked structure 200 and the lower capping layer 510. Forming the trenches 600 may include forming a mask pattern (not shown) defining the planar position of the trenches 600 on the lower capping layer 510 and etching the stacked structure 200 using the mask pattern as an etching mask. The etching of the stacked structure 200 may be performed by an anisotropic etching process.

The trenches 600 may be formed between neighboring vertical structures 300. The trenches 600 may be separated from the vertical structures 300 to expose the sidewalls of the sacrificing layers SC and the sidewalls of the insulating layers IL. The upper portions of the trenches 600 may have greater widths than the lower portions thereof. The trenches 600 may expose the top surface 100a of the substrate 100. During forming the trenches 600, the top surface 100a of the substrate 100 exposed by the trenches 600 may be recessed to a certain depth due to over etching. As shown in FIG. 1, the trenches 600 may have major axes which are parallel to the second direction D2 in a plan view. The trenches 600 may be separated in the first direction D1.

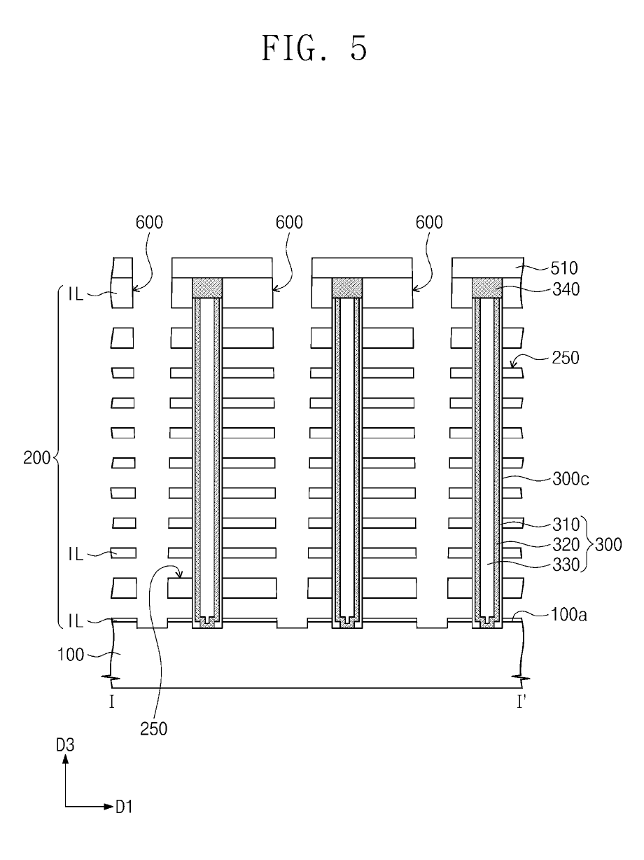

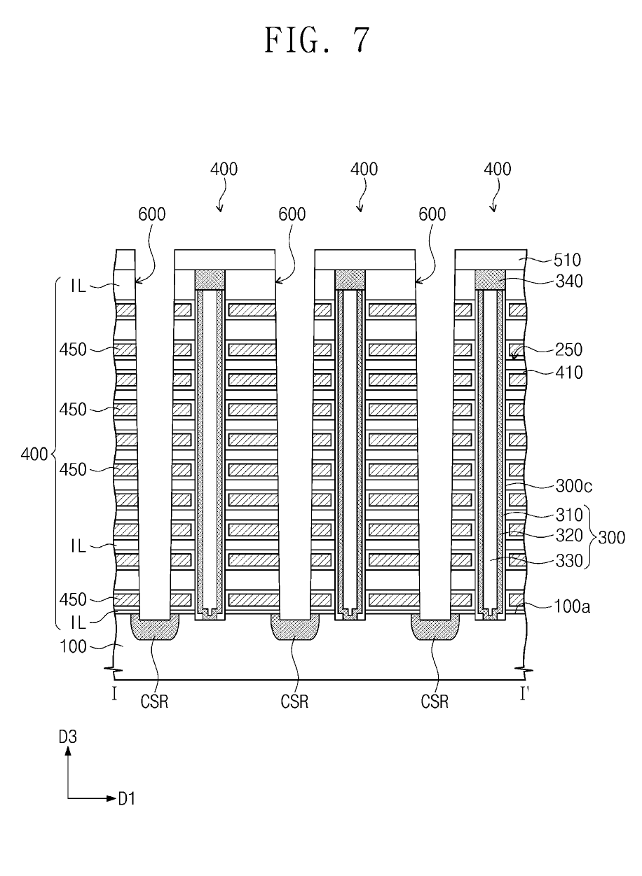

Referring to FIG. 5, sacrificing layers SC may be etched to form gate regions 250. The gate regions 250 may be vacant, and the gate regions 250 may become areas for forming gate electrode patterns 450 in FIG. 7. The gate regions 250 may be formed between the insulating layers IL and may be connected to the trenches 600. The gate regions 250 may expose portions of the sidewalls 300c of the vertical structure 300. The thickness of the gate regions 250 may be substantially the same as the thickness of the sacrificing layers SC. Etching the sacrificing layers SC may be performed by an etching process using an etching composition. The etching process may be a wet etching process.

The etching composition may include phosphoric acid, an ammonium-based compound, hydrochloric acid, and a silicon-containing compound. The sacrificing layers SC may include silicon nitride and thus may be etched by phosphoric acid as in Reaction 1. Even though an etching process is performed for a long time and phosphoric acid is consumed, the concentration of phosphoric acid may be maintained constant due to a polyphosphate-based compound. Accordingly, the etch rate of the sacrificing layers SC and the insulating layers IL may be maintained constant.

In an embodiment, the etching composition of about 150° C. to 200° C., particularly, about 155° C. to 170° C. may be supplied to the substrate 100. In the above temperature conditions, phosphoric acid may further etch silicon oxide in addition to the sacrificing layers SC. The insulating layers IL may include silicon oxide. According to exemplary embodiments, the etching composition may include the silicon-containing compound, and the etching of the insulating layers IL by the phosphoric acid may be prevented or decreased. For example, in the etching process, oxygen of the silicon-containing compound may be bonded to surfaces of the insulating layers IL and may protect the insulating layers IL. Accordingly, during the etching process, the etch rate of insulating layers IL may be low. The oxygen atoms of the silicon-containing compound may not make interaction (for example, hydrogen bond) with the surface of the sacrificing layers SC. Accordingly, the etch selectivity of the sacrificing layers SC with respect to the insulating layers IL may increase. If the silicon-containing compound is unstable, by-products may be formed, and the by-products may form particles. The by-products and/or the particles may induce defects during the manufacturing process of the semiconductor device. For example, the by-products and/or the particles may be adsorbed onto the insulating layers IL. Since the bond of the silicon atom and the oxygen atom of the silicon-containing compound is stable, the formation of by-products during the etching process may be prevented. The sacrificing layers SC may be etched to form silicon ions (for example, SiO₂H₂O). The ammonium-based compound and hydrochloric acid may remove silicon ions, which are produced during etching of the sacrificing layers SC. Accordingly, the abnormal growth of the insulating layers IL due to the silicon ions may be prevented or decreased.

During the etching process, the etching composition may be supplied onto the substrate 100 by a coating, dipping, spraying, or injecting method. If the etching composition is supplied onto the substrate 100 by a dipping method, a batch-type apparatus may be used in the etching process. If the etching composition is supplied onto the substrate 100 by a spraying method, a single wafer type apparatus may be used in the etching process. After finishing the etching process, a washing process using ultra-pure water and a drying process may be performed on the substrate 100. Ultra-pure water may mean water including impurities in about 100 ppb or less.

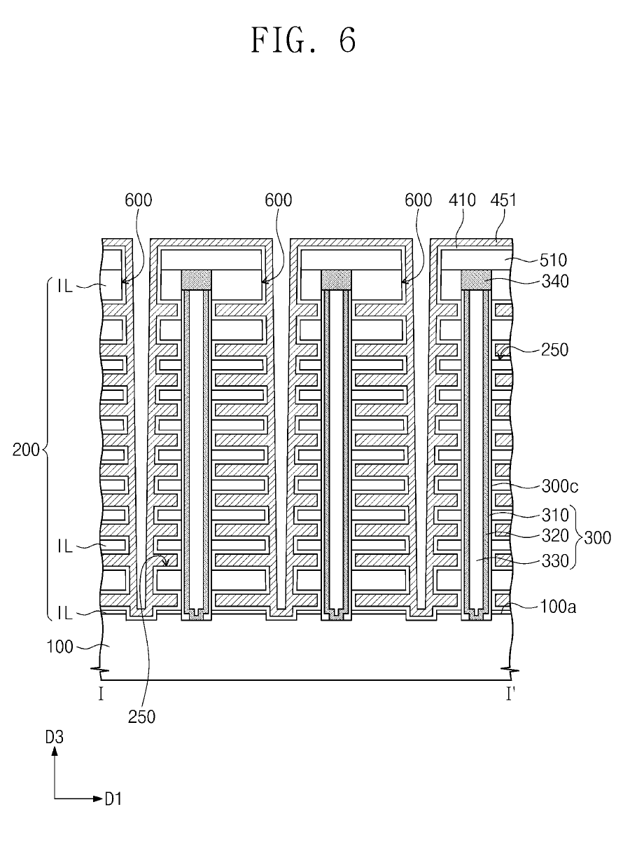

Referring to FIG. 6, a second dielectric pattern 410 and a gate conductive layer 451 may be formed on the stacked structure 200 and in the trenches 600. The second dielectric pattern 410 may be substantially conformally formed on the stacked structure 200 and in the trenches 600. The second dielectric pattern 410 may be extended into the trenches 600 and the gate regions 250. The second dielectric pattern 410 may substantially conformally cover the top surface of the uppermost insulating layer IL among the insulating layers IL, the sidewalls of the insulating layers IL exposed by the trenches 600, the tops and bottom surfaces of the insulating layers IL exposed by the gate regions 250, the sidewalls 300c of the vertical structure 300 exposed by the gate regions 250, and the top surface 100a of the substrate 100. The second dielectric pattern 410 may be formed by a deposition process. A deposition method and deposition conditions may be controlled to form the second dielectric pattern 410 with excellent step coverage. For example, the deposition process of the second dielectric pattern 410 may be performed by a chemical vapor deposition or an atomic layer deposition method. The second dielectric layer 410 may be a single layer or may be plural layers. The second dielectric pattern 410 may be a portion of a data storage layer DS of a charge trap type flash memory transistor. Exemplary embodiments of the second dielectric pattern 410 will be explained later referring to FIG. 9.

The gate conductive layer 451 may be formed on the second dielectric pattern 410. At least a portion of each of the trenches 600 and the gate regions 250 may be filled with the gate conductive layer 451. Unlike FIG. 6, each of the trenches 600 may be completely filled with the gate conductive layer 451. Even though not shown, a barrier metal layer and a metal layer may be sequentially deposited to form the gate conductive layer 451. The barrier metal layer may include, for example, metal nitride such as titanium nitride (TiN), tantalum nitride (TaN), or tungsten nitride (WN). The metal layer may include, for example, tungsten (W), aluminum (Al), titanium (Ti), tantalum (Ta), cobalt (Co), or copper (Cu).

Referring to FIGS. 1 and 7, the gate conductive layer 451 may be patterned and gate electrode patterns 450 may be formed on the gate regions 250, respectively. The patterning of the gate conductive layer 451 may be performed by an etching process. In this case, the second dielectric pattern 410 may be further etched. During the etching process of the gate conductive layer 451, the gate conductive layer 451 on the substrate 100 may be removed. The etching of the gate conductive layer 451 may be performed until the insulating layers IL on the sidewalls are removed, and the sidewalls of the insulating layers IL are exposed. Accordingly, the gate electrode patterns 450 and the second dielectric pattern 410 may be localized in the gate regions 250 to form the gate structures 400. Each of the gate structures 400 may be formed between two adjacent trenches 600. The sidewalls of the gate structures 400 may be exposed to the trenches 600. The gate structures 400 may expose the top surface 100a of the substrate 100 in the trenches 600. The exposed top surface 100a of the substrate 100 may be further etched. The gate structures 400 may have major axes which are parallel to the second direction D2 in a plan view as shown in FIG. 1. The gate structures 400 may be separated in the first direction D1.

Each of the gate structures 400 may include gate electrode patterns 450, the second dielectric pattern 410, and the insulating layers IL, which are stacked. In each of the gate structures 400, the gate electrode patterns 450 may be interposed between the insulating layers IL. The gate electrode patterns 450 may be used as a string selection line, a ground selection line and word lines. For example, the uppermost and lowermost ones of the stacked gate electrode patterns 450 may be used as the string selection line and the ground selection line, respectively. The gate electrode patterns 450 between the uppermost and the lowermost gate electrode patterns 450 may be used as the word lines.

In the gate structures 400, the second dielectric pattern 410 may be interposed between the gate electrode patterns 450 and the insulating layers IL, and the vertical structure 300 and the insulating layers IL.

Common source regions CSR may be formed in the substrate 100 exposed to the trenches 600. The common source regions CSR may be separated in the first direction D1. The common source regions CSR may be formed by an ion injection process using the gate structures 400 as an ion mask. The common source regions CSR may be overlapped with the bottom portion of the gate structures 400 in a plan view due to the diffusion of impurities. The common source regions CSR may have a different conductive type from the conductive type of the substrate 100. In a different embodiment, the common source regions CSR may be formed after forming the trenches 600 of FIG. 4.

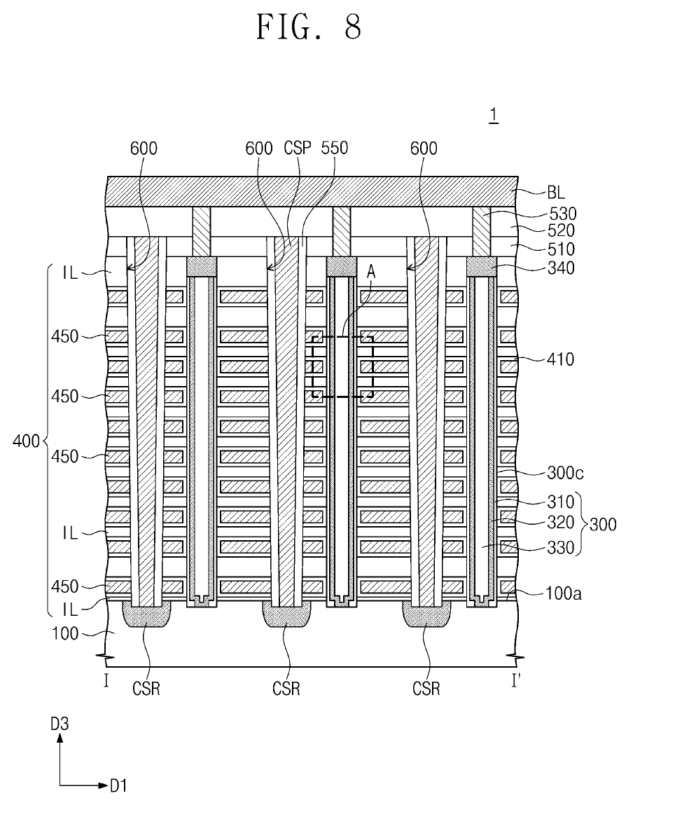

Referring to FIGS. 1 and 8, spacers 550 and common source plugs CSP may be formed in the trenches 600, respectively. The spacers 550 may cover the sidewalls of the gate structures 400. The spacers 550 may include an insulating material. The spacers 550 may be formed using, for example, silicon oxide, silicon nitride, silicon oxynitride, or a low-k material. The forming of the spacers 550 may include covering the gate structures 400 by depositing a spacer layer (not shown) in a uniform thickness on the substrate 100 and exposing the common source regions CSR by performing an etch-back process with respect to the spacer layer.

The common source plugs CSP may be formed on the spacers 550 to fill up the trenches 600. The common source plugs CSP may be connected with the common source regions CSR, respectively. The forming of the common source plug CSP may include depositing a barrier metal layer (not shown) covering the sidewalls of the spacers 550 and depositing a metal layer (not shown) on the barrier metal layer. The barrier metal layer may include, for example, at least one of tantalum (Ta), tantalum nitride (TaN), titanium (Ti), titanium nitride (TiN), tungsten (W), tungsten nitride (WN), and the combination thereof. The metal layer may include tungsten (W), aluminum (Al), titanium (Ti), tantalum (Ta), cobalt (Co), or copper (Cu). In a plan view as in FIG. 1, the major axes of the common source plugs CSP may be extended in parallel to the second direction D2.

An upper capping layer 520 may be formed on the lower capping layer 510 to cover the top surface of the common source plug CSP. The upper capping layer 520 may include an insulating material.

Bit line contact plugs 530 may be formed in the upper capping layer 520. The bit line contact plugs 530 may penetrate the upper capping layer 520 and the lower capping layer 510 to be in contact with pads 340, respectively. The bit line contact plugs 530 may electrically contact the vertical structures 300 (for example, semiconductor patterns 320) through the pads 340, respectively. Bit lines BL may be formed on the upper capping layer 520 to be in contact with the bit line contact plugs 530. As shown in FIG. 1, the bit lines may be extended in the first direction D1 in a plan view. The bit line contact plugs 530 and the bit lines BL may include a conductive material such as a metal. Accordingly, a semiconductor device 1 may be completed. The semiconductor device 1 may be a three-dimensional memory device.

FIG. 9 is a diagram for explaining insulating patterns of a semiconductor device according to exemplary embodiments, and illustrates an enlarged diagram of region A of FIG. 8. Hereinafter, a single insulating layer, plural gate electrode patterns, and a single vertical structure will be described in the explanation of FIG. 9 for the brevity of explanation.

Referring to FIGS. 8 and 9, a first dielectric pattern 310 may include a tunnel insulating layer 311, a charge storage layer 312, and a first blocking insulating layer 313. The tunnel insulating layer 311 may be extended along a vertical structure 300. The charge storage layer 312 and the first blocking insulating layer 313 may be stacked on the tunnel insulating layer 311. The tunnel insulating layer 311 may be formed using a material having a lower dielectric constant than the first blocking insulating layer 313. The tunnel insulating layer 311 may include, for example, at least one selected from oxide, nitride or oxynitride. Alternatively, the tunnel insulating layer 311 may include a high-k material. The high-k material means an insulating material having a higher dielectric constant than silicon oxide and may include zirconium oxide, aluminum oxide and/or hafnium oxide. The charge storage layer 312 may be interposed between the tunnel insulating layer 311 and the first blocking insulating layer 313. The charge storage layer 312 may include at least one of a charge trap insulating layer, a floating gate electrode or conductive nano dots. The first blocking insulating layer 313 may include a high-k material.

A second dielectric pattern 410 may include a second blocking insulating layer. The second blocking insulating layer may be interposed between the gate electrode pattern 450 and the first dielectric pattern 310, and the gate electrode pattern 450 and the insulating layer IL. The second blocking insulating layer may include a high-k material. In an embodiment, the first blocking insulating layer 313 may include a high-k material, and the second blocking insulating layer may be a material having a lower dielectric constant than the first blocking dielectric layer 313. In another embodiment, the second blocking dielectric layer may include one of high-k materials, and the first blocking insulating layer 313 may be a material having a lower dielectric constant than the second blocking insulating layer.

The first dielectric pattern 310 and the second dielectric pattern 410 may function as data storage layers. Data stored in the data storage layer may be changed using Fowler-Nordheim tunneling. The Fowler-Nordheim tunneling may be induced by a voltage difference between the vertical structure 300 and the gate electrode pattern 450.

Different from the figure, the second dielectric pattern 410 may not be formed. In another embodiment, the first blocking insulating layer 313 may not be formed.

Hereinafter, the etching composition and an etching method using thereof will be explained referring to experimental embodiments and comparative embodiments.

Preparation of Etching Composition

1. Preparation of Compound of Formula 4

3-aminopropyl silanetriol (CAS No. 58160-99-9) and tris(ethylmethylamino)chlorosilane (CAS No. 1378825-94-5) were mixed and stirred to synthesize a compound of Formula 4 (tri(tri-(ethylmethylaminosilane)aminopropylsiloxane).

Identification of the Preparation of Compound of Formula 4 (FT-IR)

The reactants and the product were analyzed by Fourier Transform Infrared spectroscopy by using an infrared spectrum measurement apparatus.

From the analysis results of the reactants, Si—OH peaks of 3-aminopropylsilanetriol were shown at about 835-955 cm⁻¹ and about 3200-3700 cm⁻¹, and an Si—Cl peak of tris(ethylmethylamino)chlorosilane was shown at about 470-550 cm⁻¹. From the analysis results of the product, the Si—OH peaks and the Si—Cl peak were disappeared, and a peak was detected at about 1100 cm⁻¹. The peak at 1100 cm⁻¹ corresponded to a peak of Si—O—Si. From the results, it may be found that the Si—OH bond of the reactant, 3-aminopropylsilanetriol and the Si—Cl bond of the reactant, tris(ethylmethylamino)chlorosilane were broken, and the compound of Formula 4 having an Si—O—Si bond was formed.

2. Preparation and Identification of Compound of Formula 5

3-aminopropylsilanetriol and tris(diethylamino)chlorosilane were mixed and stirred to synthesize a compound of Formula 5.

Tris(diethylamino)chlorosilane was purchasable from Gelest Co. (Product code SIT8710.6).

Identification of the Preparation of Compound of Formula 5 (FT-IR

The reactants and the product were analyzed by Transform Infrared spectroscopy. From the analysis results of the reactants, Si—OH peaks of 3-aminopropylsilanetriol were shown at about 835-955 cm⁻¹ and about 3200-3700 cm⁻¹, and an Si—Cl peak of tris(ethylmethylamino)chlorosilane was shown at about 470-550 cm⁻¹. From the analysis results of the product, the SI—OH peak and the Si—Cl peak were disappeared, and a peak was detected at about 1100 cm⁻¹. From the results, it may be found that the Si—OH bond of the reactant (3-aminopropylsilanetriol) and the Si—Cl bond of the reactant (tris(diethylamino)chlorosilane) were broken, and the compound of Formula 5 having an Si—O—Si bond was formed.

3. Preparation of Etching Composition

### Experimental Examples

As shown in Table 1 below, phosphoric acid, a silicon-containing compound, an ammonium-based compound, hydrochloric acid, and a polyphosphate-based compound were mixed to prepare etching compositions. In this case, the phosphoric acid was an aqueous solution of 85% phosphoric acid Ammonium chloride was used as the ammonium-based compound. Pyrophosphoric acid was used as the polyphosphate-based compound.

TABLE 1

| | Composition (wt %) | | | | | |
|---|---|---|---|---|---|---|
| | Phos- | Silicon- | | Ammo- | Hydro- | Pyrophos- |
| | phoric | containing | | nium | chloric | phoric |
| | acid | compound | | chloride | acid | acid |
| Experimental | 96 | Compound of | 2.5 | 0.5 | 1 | — |
| Example 1 | | Formula 4 | | | | |
| Experimental | 92 | Compound of | 2.5 | 0.5 | 5 | — |
| Example 2 | | Formula 4 | | | | |
| Experimental | 87 | Compound of | 2.5 | 0.5 | 10 | — |
| Example 3 | | Formula 4 | | | | |
| Experimental | 95 | Compound of | 3.0 | 1 | 1 | — |
| Example 4 | | Formula 5 | | | | |
| Experimental | 91 | Compound of | 3.0 | 1 | 5 | — |
| Example 5 | | Formula 5 | | | | |
| Experimental | 86 | Compound of | 3.0 | 1 | 10 | — |
| Example 6 | | Formula 5 | | | | |
| Experimental | 96 | Compound of | 2.5 | 0.5 | — | 1 |
| Example 7 | | Formula 4 | | | | |
| Experimental | 92 | Compound of | 2.5 | 0.5 | — | 5 |
| Example 8 | | Formula 4 | | | | |
| Experimental | 87 | Compound of | 2.5 | 0.5 | — | 10 |
| Example 9 | | Formula 4 | | | | |
| Experimental | 95 | Compound of | 3.0 | 1 | — | 1 |
| Example 10 | | Formula 5 | | | | |
| Experimental | 91 | Compound of | 3.0 | 1 | — | 5 |
| Example 11 | | Formula 5 | | | | |
| Experimental | 86 | Compound of | 3.0 | 1 | — | 10 |
| Example 12 | | Formula 5 | | | | |
| Experimental | 91 | Compound of | 2.5 | 0.5 | 1 | 5 |
| Example 13 | | Formula 4 | | | | |
| Experimental | 90.5 | Compound of | 3 | 0.5 | 1 | 5 |
| Example 14 | | Formula 5 | | | | |

### Comparative Examples

As shown in Table 2 below, phosphoric acid, a silicon-containing compound, hydrochloric acid and a polyphosphate-based compound were mixed to prepare etching compositions. In this case, the phosphoric acid was an aqueous solution of 85% phosphoric acid.

TABLE 2

| | Composition (wt %) | | | | | |
|---|---|---|---|---|---|---|
| | Phos- | Silicon- | | Ammo- | Hydro- | Pyrophos- |
| | phoric | containing | | nium | chloric | phoric |
| | acid | compound | | chloride | acid | acid |
| Comparative | 100 | — | — | — | — | — |
| Example 1 | | | | | | |
| Comparative | 94.5 | Compound of | 2.5 | 3 | — | — |
| Example 2 | | Formula 4 | | | | |
| Comparative | 94 | Compound of | 3.0 | 3 | — | — |
| Example 3 | | Formula 5 | | | | |
| Comparative | 84.5 | Compound of | 3 | 0.5 | 0 | 12 |
| Example 4 | | Formula 5 | | | | |
| Comparative | 85 | Compound of | 2.5 | 0.5 | 12 | |
| Example 5 | | Formula 4 | | | | |
| Comparative | 84 | Compound of | 3.0 | 1 | 6 | 6 |
| Example 6 | | Formula 5 | | | | |

4. Etching Using Etching Composition

(1) Etching of Silicon Nitride Layer

A silicon oxide layer including SixNy was formed (x and y are each independently a positive integer). An etching composition was added to a beaker, and the beaker was heated until the temperature of the etching composition reached about 165° C. The etching composition of about 165° C. was supplied to the silicon oxide layer for about 60 minutes. When the etching composition was supplied to the silicon oxide layer, the etch rate was measured (hereinafter, referred to as initial etch rate). Solutions from the silicon oxide layer were collected. When the concentration of silicon ions in the solution reached about 100 ppm, etch rate was measured (hereinafter, will be referred to as dummy etch rate). The measurement of the etch rate was performed using a thin film thickness measurement apparatus, and the thin film thickness measurement apparatus was Ellipsometer (NANO VIEW, SE MG-1000).

A silicon nitride layer was etched using each of the etching compositions of Experimental Examples 1 to 14 and Comparative Examples 1 to 4.

(2) Etching of Silicon Oxide Layer

A silicon oxide layer represented by SixOy (where, x and y are each independently a positive integer) was formed using tetraethoxysilane (TEOS). The silicon oxide layer was etched using each of the etching compositions of Experimental Examples 1 to 14 and Comparative Examples 1 to 4 by the same method for etching the silicon nitride layer. The initial etch rate and the dummy etch rate of the silicon oxide layer were measured.

Table 3 shows the measure results of the etch rates of the silicon oxide layer and the silicon nitride layer using the etching compositions of the experimental examples of the disclosure and the comparative examples.

TABLE 3

| | | | | Silicon oxide layer | | |
|---|---|---|---|---|---|---|
| | | | | | | Dummy |
| | | | Dummy | | | etch |
| | Silicon | | etch | | | rate |
| | nitride layer | | rate with | | | with |
| | Initial | Dummy | respect | | | respect |
| | etch | etch | to initial | Initial | Dummy | to initial |
| | rate | rate | etch rate | etch rate | etch rate | etch rate |
| | (Å/min) | (Å/min) | (Å/min) | (Å/min) | (Å/min) | (Å/min) |
| Experimental | 70.33 | 69.01 | 98.12 | 0.30 | 0.15 | 50.00 |
| Example 1 | | | | | | |
| Experimental | 70.87 | 68.13 | 96.13 | 0.30 | 0.14 | 46.67 |
| Example 2 | | | | | | |
| Experimental | 70.38 | 68.29 | 97.03 | 0.30 | 0.15 | 50.00 |
| Example 3 | | | | | | |
| Experimental | 73.01 | 70.63 | 96.74 | 0.30 | 0.12 | 40.00 |
| Example 4 | | | | | | |
| Experimental | 70.12 | 69.90 | 99.69 | 0.30 | 0.12 | 40.00 |
| Example 5 | | | | | | |
| Experimental | 71.26 | 69.63 | 97.71 | 0.30 | 0.12 | 40.00 |
| Example 6 | | | | | | |
| Experimental | 70.68 | 68.14 | 96.41 | 0.30 | 0.17 | 56.67 |
| Example 7 | | | | | | |
| Experimental | 72.57 | 69.73 | 96.09 | 0.30 | 0.12 | 40.00 |
| Example 8 | | | | | | |
| Experimental | 71.69 | 70.40 | 98.20 | 0.30 | 0.17 | 56.67 |
| Example 9 | | | | | | |
| Experimental | 71.76 | 70.83 | 98.70 | 0.30 | 0.15 | 50.00 |
| Example 10 | | | | | | |
| Experimental | 71.68 | 69.87 | 97.47 | 0.30 | 0.14 | 46.67 |
| Example 11 | | | | | | |
| Experimental | 70.59 | 69.38 | 98.29 | 0.30 | 0.18 | 60.00 |
| Example 12 | | | | | | |
| Experimental | 71.58 | 68.26 | 95.36 | 0.30 | 0.15 | 50.00 |
| Example 13 | | | | | | |
| Experimental | 70.26 | 69.48 | 98.89 | 0.30 | 0.15 | 50.00 |
| Example 14 | | | | | | |
| Comparative | 72.89 | 72.63 | 99.64 | 3.21 | 0.44 | 13.71 |
| Example 1 | | | | | | |
| Comparative | 70.34 | 69.82 | 99.26 | 0.30 | 0.03 | 10.00 |
| Example 2 | | | | | | |
| Comparative | 70.38 | 69.14 | 98.24 | 0.30 | 0.01 | 3.33 |
| Example 3 | | | | | | |
| Comparative | 70.29 | 69.51 | 98.89 | 0.32 | 0.14 | 43.75 |
| Example 4 | | | | | | |
| Comparative | 62.57 | 59.24 | 94.67 | 0.30 | 0.15 | 50.00 |
| Example 5 | | | | | | |
| Comparative | 63.46 | 59.63 | 93.96 | 0.30 | 0.17 | 56.67 |
| Example 6 | | | | | | |

Referring to Table 3, in the experimental examples and the comparative examples, the etch rate of the silicon nitride layer was maintained constant in accordance with time. The etch rate of the silicon oxide layer was maintained relatively constant in accordance with time in the experimental examples, but the etch rate of the silicon oxide layer was largely decreased according to the lapse of time in the Comparative Examples 1 to 3. In Comparative Example 1 and Comparative Example 4, the initial etch rate of the silicon oxide layer was relatively high. That is, the etch selectivity of the silicon nitride layer with respect to the silicon oxide layer in the initial etching process in Comparative Example 1 and Comparative Example 4 was lower than that of the experimental examples. In Comparative Example 5 and Comparative Example 6, the etch rate of the silicon nitride layer was smaller than those of the experimental examples.

According to the disclosure, the etch selectivity of a silicon nitride layer with respect to a silicon oxide layer may be high in an etching process using an etching composition. In addition, an etch rate may be maintained constant even though an etching process is performed for a long time.

Although the exemplary embodiments of the present disclosure have been described, it is understood that the present disclosure should not be limited to these exemplary embodiments but various changes and modifications can be made by one ordinary skilled in the art within the spirit and scope of the present disclosure as hereinafter claimed.

1. A composition for etching, the composition comprising:
phosphoric acid;
an ammonium-based compound;
a hydrochloric acid or a polyphosphate-based compound; and
a silicon-containing compound represented by Formula 1: 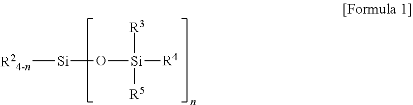
wherein in Formula 1:
R² is any one selected from hydrogen, an alkyl group of 1 to 10 carbon atoms, an amino alkyl group of 1 to 10 carbon atoms, an amino alkoxy group of 1 to 10 carbon atoms, and an alkoxy amino group of 1 to 10 carbon atoms,
each of R³, R⁴ and R⁵ is hydrogen, an alkyl group of 1 to 10 carbon atoms, an amino alkyl group of 1 to 10 carbon atoms, an amino alkoxy group of 1 to 10 carbon atoms, an alkoxy amino group of 1 to 10 carbon atoms, or an alkyl substituted or unsubstituted amino group of 1 to 10 carbon atoms,
at least one of R³, R⁴ or R⁵ is an alkoxy amino group of 1 to 10 carbon atoms or an alkyl substituted or unsubstituted amino group of 1 to 10 carbon atoms, and
n is 2 or 3.

2. The composition for etching of claim 1, wherein:
a composition ratio of the phosphoric acid is from about 65 wt % to about 97 wt %,
a composition ratio of the ammonium-based compound is from about 0.01 wt % to about 10 wt %,
a composition ratio of the hydrochloric acid and the polyphosphate-based compound is from about 1 wt % to about 10 wt %, and
a composition ratio of the silicon-containing compound is from about 0.01 wt % to about 15 wt %.

3. The composition for etching of claim 1, wherein the silicon-containing compound is represented by Formula 2:

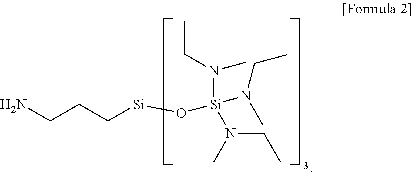

4. The composition for etching of claim 1, wherein the silicon-containing compound is represented by Formula 2:

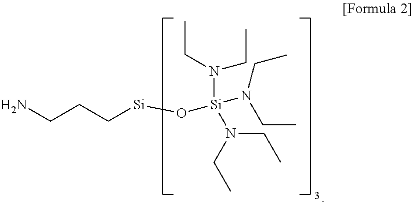

5. The composition for etching of claim 1, wherein the ammonium-based compound comprises ammonium chloride, ammonium phosphate, ammonium acetate, ammonium sulfate, ammonium formate, or a metal amine complex.

6. The composition for etching of claim 1, wherein the polyphosphate-based compound comprises pyrophosphoric acid, pyrophosphate, tripolyphosphoric acid, or tripolyphosphate.

7. A method of etching a silicon nitride layer, the method comprising:
preparing a substrate on which a silicon nitride layer is formed; and
performing an etching process on the silicon nitride layer using a composition for etching to remove the silicon nitride layer, wherein the composition for etching comprises:
phosphoric acid;
an ammonium-based compound;
hydrochloric acid or a polyphosphate-based compound; and
a silicon-containing compound represented by Formula 1: 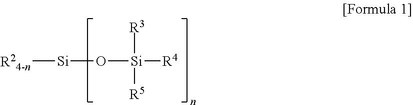
wherein in Formula 1:
R² is any one selected from hydrogen, an alkyl group of 1 to 10 carbon atoms, an amino alkyl group of 1 to 10 carbon atoms, an amino alkoxy group of 1 to 10 carbon atoms, and an alkoxy amino group of 1 to 10 carbon atoms,
each of R³, R⁴ and R⁵ is hydrogen, an alkyl group of 1 to 10 carbon atoms, an amino alkyl group of 1 to 10 carbon atoms, an amino alkoxy group of 1 to 10 carbon atoms, an alkoxy amino group of 1 to 10 carbon atoms, or an alkyl substituted or unsubstituted amino group of 1 to 10 carbon atoms,
at least one of R³, R⁴ or R⁵ is an alkoxy amino group of 1 to 10 carbon atoms or an alkyl substituted or unsubstituted amino group of 1 to 10 carbon atoms, and
n is 2 or 3.

8. The method of etching a silicon nitride layer of claim 7, further comprising:
forming a silicon oxide layer on the substrate before the etching process, wherein
the etching process comprises applying the composition for etching on the silicon oxide layer and the silicon nitride layer.

9. The method of etching a silicon nitride layer of claim 8, wherein an etching rate of the silicon nitride layer is greater than an etching rate of the silicon oxide layer during the etching process.

10. The method of etching a silicon nitride layer of claim 7, wherein:
a composition ratio of the phosphoric acid is from about 65 wt % to about 97 wt %,
a composition ratio of the ammonium-based compound is from about 0.01 wt % to about 10 wt %,
a composition ratio of the hydrochloric acid and the polyphosphate-based compound is from about 1 wt % to about 10 wt %, and
a composition ratio of the silicon-containing compound is from about 0.01 wt % to about 15 wt %.

11. The method of etching a silicon nitride layer of claim 7, wherein the silicon-containing compound is represented by Formula 2 or Formula 3:

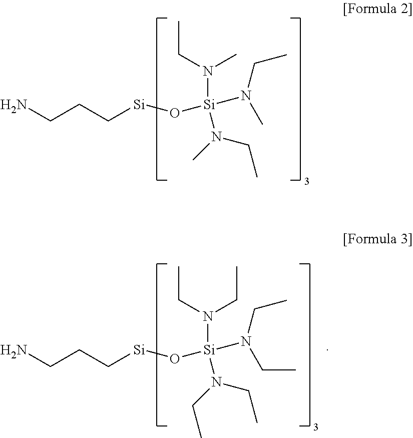

12. The method of etching a silicon nitride layer of claim 7, wherein the ammonium-based compound comprises ammonium chloride, ammonium phosphate, ammonium acetate, ammonium sulfate, ammonium formate, or a metal amine complex.

13. The method of etching a silicon nitride layer of claim 7, wherein the polyphosphate-based compound comprises pyrophosphoric acid, pyrophosphate, tripolyphosphoric acid, or tripolyphosphate.

14. A method for manufacturing a semiconductor device, the method comprising:
forming a stacked structure by alternately and repeatedly forming insulating layers and sacrificing layers on a substrate;
forming a trench penetrating the stacked structure; and
removing the sacrificing layers by performing an etching process using a composition for etching, wherein the composition for etching comprises:
phosphoric acid;
an ammonium-based compound;
hydrochloric acid or a polyphosphate-based compound; and
a silicon-containing compound represented by Formula 1: 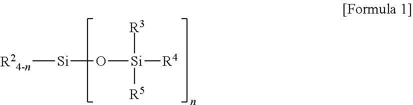
wherein in Formula 1:
R² is any one selected from hydrogen, an alkyl group of 1 to 10 carbon atoms, an amino alkyl group of 1 to 10 carbon atoms, an amino alkoxy group of 1 to 10 carbon atoms, and an alkoxy amino group of 1 to 10 carbon atoms,
each of R³, R⁴ and R⁵ is hydrogen, an alkyl group of 1 to 10 carbon atoms, an amino alkyl group of 1 to 10 carbon atoms, an amino alkoxy group of 1 to 10 carbon atoms, an alkoxy amino group of 1 to 10 carbon atoms, or an amino group of 1 to 10 carbon atoms unsubstituted or substituted with an alkyl group,
at least one of R³, R⁴ or R⁵ is an alkoxy amino group of 1 to 10 carbon atoms or an alkyl substituted or unsubstituted amino group of 1 to 10 carbon atoms, and
n is 2 or 3.

15. The method for manufacturing a semiconductor device of claim 14, wherein:
a composition ratio of the phosphoric acid is from about 65 wt % to about 97 wt %,
a composition ratio of the ammonium-based compound is from about 0.01 wt % to about 10 wt %,
a composition ratio of the hydrochloric acid and the polyphosphate-based compound is from about 1 wt % to about 10 wt %, and
a composition ratio of the silicon-containing compound is from about 0.01 wt % to about 15 wt %.

16. The method for manufacturing a semiconductor device of claim 14, wherein the sacrificing layers comprise silicon nitride and the insulating layers comprise silicon oxide.

17. The method for manufacturing a semiconductor device of claim 16, wherein the sacrificing layers have a higher etching rate than the insulating layers during the etching process.

18. The method for manufacturing a semiconductor device of claim 14, wherein the silicon-containing compound is represented by Formula 2 or Formula 3:

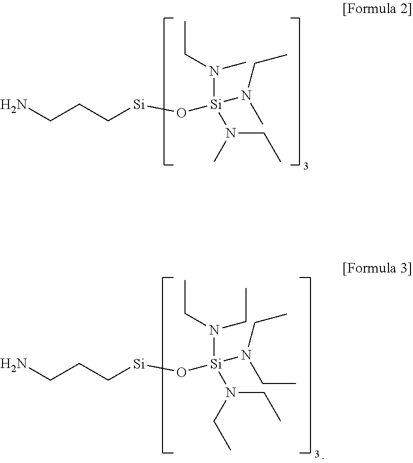

19. The method for manufacturing a semiconductor device of claim 14, further comprising:
forming gate regions between the insulating layers after the etching process, wherein
the gate regions are connected with the trench.

20. The method for manufacturing a semiconductor device of claim 14, further comprising:
forming openings penetrating the stacked structure; and
forming a semiconductor pattern separated from the trench in the openings, wherein
the forming of the semiconductor patterns is performed before forming the trench.

21-24. (canceled)
